(19) United States
(12) Patent Application Publication
(10) Pub. No.: US 2018/0259577 A1
(43) Pub. Date: Sep. 13, 2018

(54) ELECTRONIC CONTROL APPARATUS AND METHOD

(71) Applicant: HITACHI AUTOMOTIVE SYSTEMS, LTD., Hitachinaka-shi, lbaraki (JP)

(72) Inventors: Akihito KUBOTA, Isesaki-shi, Gunma (JP); Koji YUASA, Isesaki-shi, Gunma (JP); Toshihisa ARAI, Isesaki-shi, Gunma (JP)

(73) Assignee: HITACHI AUTOMOTIVE SYSTEMS, LTD., Hitachinaka-shi, Ibaraki (JP)

(21) Appl. No.: 15/758,484

(22) PCT Filed: Nov. 2, 2016
(86) PCT No.: PCT/JP2016/082656

§ 371 Date: Mar. 8, 2018

(30) Foreign Application Priority Data
Nov. 5, 2015 (JP) 2015-217550

(51) Int. Cl. G01R 31/3187; G01R 31/317; G06F 11/27

(52) U.S. Cl. CPC G01R 31/3187; G06F 11/27; G01R 31/31724

(57) ABSTRACT

An electronic control apparatus comprises a microcomputer that incorporates a diagnosis circuit for a hardware resource and a processor. The processor of the electronic control apparatus is configured to, when the diagnosis circuit determines that the hardware resource has failed, substitute a function provided by the failed hardware resource with a function provided by another hardware resource.

### TECHNICAL FIELD

The present invention relates to electronic control apparatus and method.

### BACKGROUND ART

In some electronic control apparatuses, a microcomputer is provided with a BIST (Built In Self Test) for diagnosing hardware resources such as a timer, an I/O circuit, and an A/D converter, as disclosed in JP 2012-181564 A (Patent Document 1). The BIST is implemented by integrating some LSI diagnosis functions into an LSI (Large Scale Integration) chip, and includes a test pattern generator circuit and a circuit for comparing test results with expected values. The BIST inputs a test pattern into a target hardware resource and compares test results output from the hardware resource with expected values so as to determine whether the hardware resource has failed.

### REFERENCE DOCUMENT LIST

### Patent Document

Patent Document 1: JP 2012-181564 A

### SUMMARY OF THE INVENTION

### Problem to be Solved by the Invention

When the BIST determines that a hardware resource has failed, it is desirable to prohibit the use of the hardware resource which may lead to out-of-control status under the standard for functional safety ISO26262. However, if the use of an important hardware resource is prohibited, a system to be controlled cannot be controlled continuously.

In view of the foregoing, it is an object of the present invention to provide electronic control apparatus and method that allow continuous control of a system to be controlled, even when a hardware resource has failed.

### Means for Solving the Problem

An electronic control apparatus comprises a microcomputer having a diagnosis circuit for a hardware resource and a processor. The processor of the electronic control apparatus is configured to, when the diagnosis circuit determines that the hardware resource has failed, substitute a function provided by the failed hardware resource with a function provided by another hardware resource.

An electronic control method comprises utilizing a microcomputer incorporating a diagnosis circuit for a hardware resource to, when the diagnosis circuit determines that the hardware resource has failed, substitute a function provided by the failed hardware resource with a function provided by another hardware resource.

### Effects of the Invention

According to the present invention, even if a hardware resource has failed, a system to be controlled can be controlled continuously.

### BRIEF DESCRIPTION OF THE DRAWINGS

FIG. 1 is a system diagram illustrating an example of an internal combustion engine mounted in a vehicle.

FIG. 2 is a block diagram illustrating an example of an electronic circuit board.

FIG. 3 is a block diagram illustrating an example of a BIST.

FIG. 4 is a block diagram illustrating an example of a timer.

FIG. 5 is a flowchart illustrating an example of initialization processing.

FIG. 6 is an explanatory diagram illustrating a method of identifying a failed portion of a timer.

FIG. 7 is a flowchart illustrating an example of processing for identifying a failed portion of a timer.

FIG. 8 is an explanatory diagram illustrating a method of identifying a failed portion of an I/O circuit.

FIG. 9 is an explanatory diagram illustrating another method of identifying a failed portion of an I/O circuit.

FIG. 10 is a flowchart illustrating an example of processing for identifying a failed portion of an I/O circuit.

FIG. 11 is an explanatory diagram illustrating a method of identifying a failed portion of a nonvolatile memory.

FIG. 12 is a flowchart illustrating an example of processing for identifying a failed portion of a nonvolatile memory.

FIG. 13 is an explanatory diagram illustrating a method of identifying a failed portion of a volatile memory.

FIG. 14 is a flowchart illustrating an example of processing for identifying a failed portion of a volatile memory.

FIG. 15 is an explanatory diagram of a timer function.

FIG. 16 is an explanatory diagram illustrating a method of substituting for a timer.

FIG. 17 is an explanatory diagram illustrating the outline of processing for substituting for a timer.

FIG. 18 is an explanatory diagram illustrating a method of substituting for a volatile memory.

FIG. 19 is an explanatory diagram illustrating a method of substituting for an arithmetic unit.

### MODE FOR CARRYING OUT THE INVENTION

Embodiments for implementing the present invention will be described in detail below with reference to the accompanying drawings.

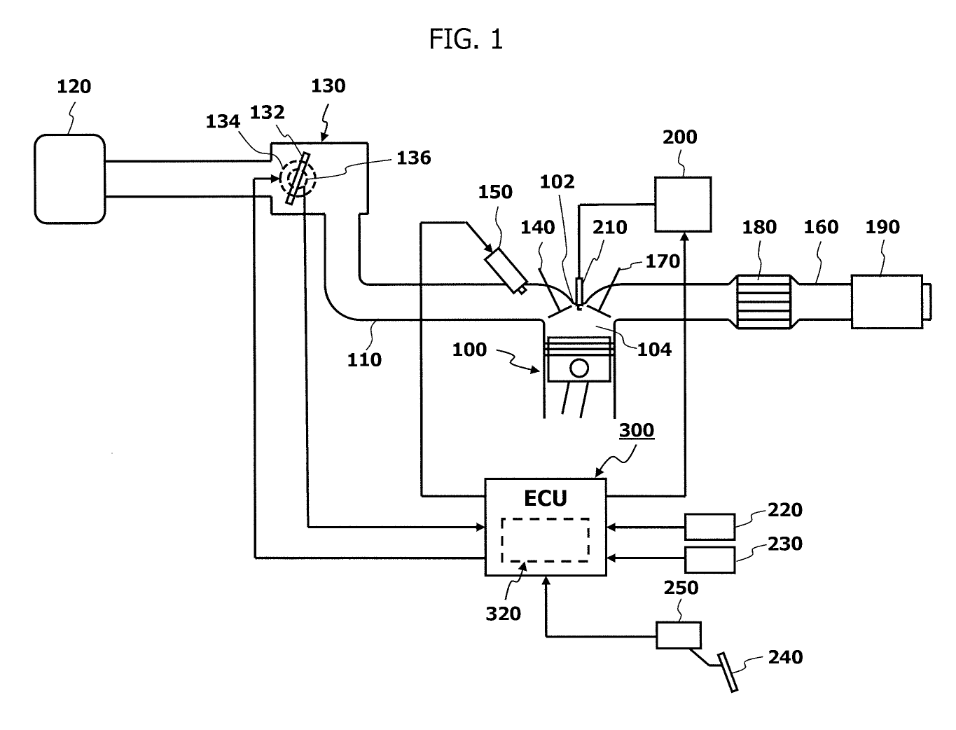

FIG. 1 illustrates an example of an internal combustion engine mounted in a vehicle.

Along an intake passage 110 of an internal combustion engine 100, provided are an air cleaner 120 for filtrating dust, etc. in the air, an electric throttle chamber 130, and an intake valve 140 that opens and closes under the control of a valve train (not illustrated), in this order in the flow direction of intake air. At some point of intake passage 110 between electric throttle chamber 130 and intake valve 140, attached is an electric fuel injection valve 150 for injecting a fuel toward a disc of intake valve 140.

Electric throttle chamber 130 includes a throttle valve 132 for adjusting an intake flow rate, an actuator 134 such as a stepping motor for rotating throttle valve 132, and a throttle position sensor 136 such as a potentiometer for detecting the degree of opening (throttle opening) of throttle valve 132. Electric throttle chamber 130 opens and closes throttle valve 132 using actuator 134 in response to an external opening signal.

On the other hand, along an exhaust passage 160 of internal combustion engine 100, provided are exhaust valves 170, a three-way catalyst converter 180 that simultaneously reduces and purifies CO (carbon monoxides), HC (hydrocarbon) and NOx (nitrogen oxides) in the exhaust gas, and a muffler 190 for muffling exhaust noise, in this order in the flow direction of exhaust gas.

Also, a spark plug 210 is attached to a cylinder head 102 of internal combustion engine 100 opposite to a combustion chamber 104. The spark plug 210 is to ignite the fuel/air mixture by an electric spark in response to spark current from a distributer 200. Here, distributer 200 distributes spark current to ignition plugs 210 provided in each cylinder of internal combustion engine 100 at an appropriate timing according to an operational condition.

Provided at predetermined positions of internal combustion engine 100 are a rotational speed sensor 220 for detecting the rotational speed of internal combustion engine 100 and a load sensor 230 for detecting load of internal combustion engine 100. Here, the load of internal combustion engine 100 can be represented by a state variable closely relating to an output torque of internal combustion engine 100 such as an intake flow rate, an intake pressure, or a supercharging pressure, for example.

Accelerator pedal 240, operated by a driver of a vehicle, is provided with an acceleration sensor 250 for detecting an operation amount of the accelerator pedal 240 (accelerator operation amount). Here, acceleration sensor 250 can be, for example, a potentiometer.

Output signals from throttle position sensor 136, rotational speed sensor 220, load sensor 230, and acceleration sensor 250 are input to an electronic control apparatus 300.

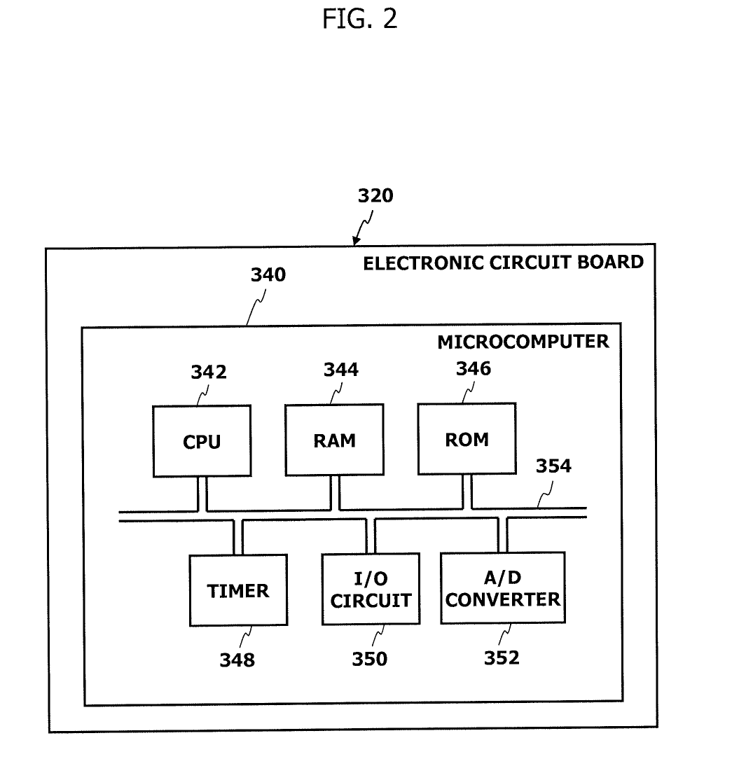

Electronic control apparatus 300 incorporates an electronic circuit board 320 on which various electronic components are mounted. As illustrated in FIG. 2, a microcomputer 340 is mounted on electronic circuit board 320. Microcomputer 340 integrally incorporates a CPU (Central Processing Unit) 342 as an example of processor, a RAM (Random Access Memory) 344 as an example of volatile memory, a ROM (Read Only Memory) 346 as an example of nonvolatile memory, a timer 348 for measuring time, an I/O circuit 350, an A/D converter 352, and a bus 354 that connects the above components with one another. That is, microcomputer 340 is produced by integrating CPU 342, RAM 344, ROM 346, timer 348, I/O circuit 350, A/D converter 352, and bus 354 into one chip.

Electronic control apparatus 300 executes control programs stored in ROM 346 to thereby electronically control electric throttle chamber 130, fuel injection valve 150, and distributer 200 individually in accordance with the throttle opening, the rotational speed, the load, the accelerator operation amount, etc.

In other words, electronic control apparatus 300 determines fuel injection amount and timing according to the rotational speed and load of internal combustion engine 100 and outputs, when the crank angle reaches the fuel injection timing, an actuation signal corresponding to the fuel injection amount to fuel injection valve 150. Also, electronic control apparatus 300 determines an ignition timing according to the rotational speed and load of internal combustion engine 100 and outputs, when the crank angle reaches the ignition timing, an actuation signal to distributer 200. Furthermore, electronic control apparatus 300 determines a target throttle opening according to an accelerator operation amount and its variation and then, executes feedback control on actuator 134 of electric throttle chamber 130 according to a difference between the target throttle opening and an actual throttle opening.

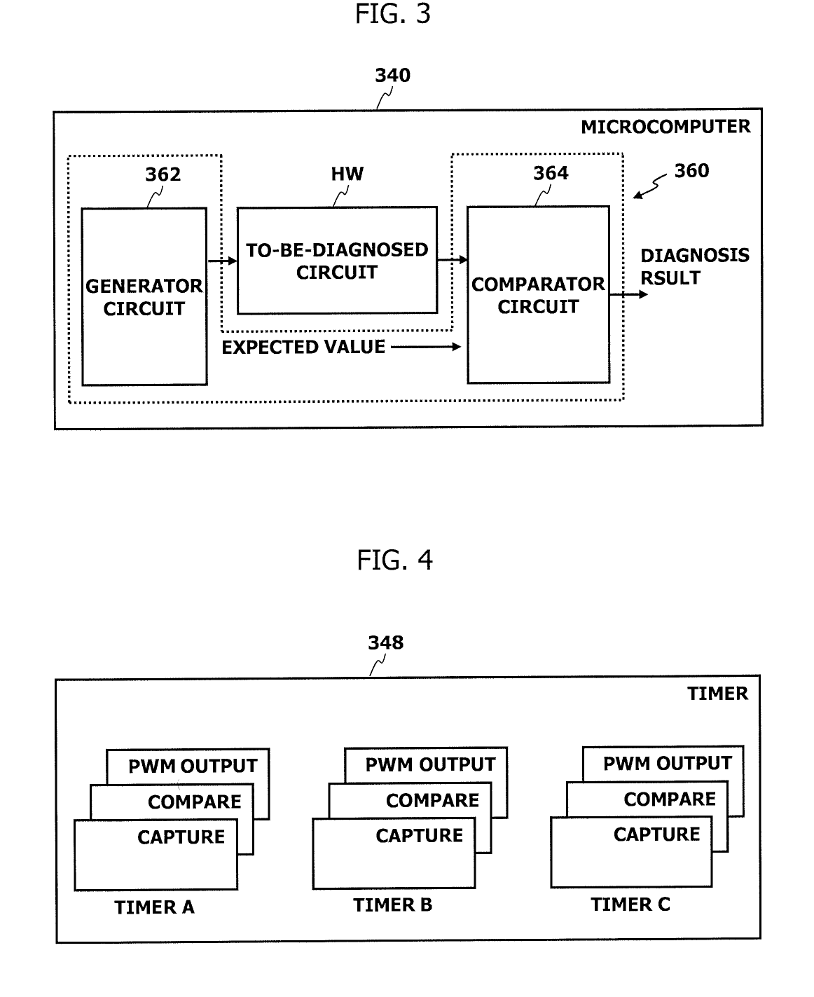

Also, microcomputer 340 incorporates a BIST 360 as an example of a diagnosis circuit for diagnosing hardware resources thereof, e.g., CPU 342, RAM 344, ROM 346, timer 348, I/O circuit 350, and A/D converter 352. As illustrated in FIG. 3, BIST 360 includes a generator circuit 362 for generating a test pattern to be input to a to-be-diagnosed circuit (hardware resource) HW and a comparator circuit 364 for comparing an output of to-be-diagnosed circuit HW with an expected value to determine whether a fault has occurred.

BIST 360 checks whether a hardware resource has failed in each group that provides a predetermined function. As illustrated in FIG. 4, for example, timer 348 for measuring time includes plural timers A to C each having ‘capture’, ‘compare’, and ‘PWM (Pulse Width Modulation) output’ functions. However, BIST 360 can only check whether a hardware resource has failed in a broadly defined group of timers for measuring time, but cannot determine the presence or absence of a fault in individual timers A to C.

In this embodiment, CPU 342 of microcomputer 340 is configured to, when BIST 360 determines that a hardware resource has failed, substitute for the function provided by the failed hardware resource with that provided by another hardware resource.

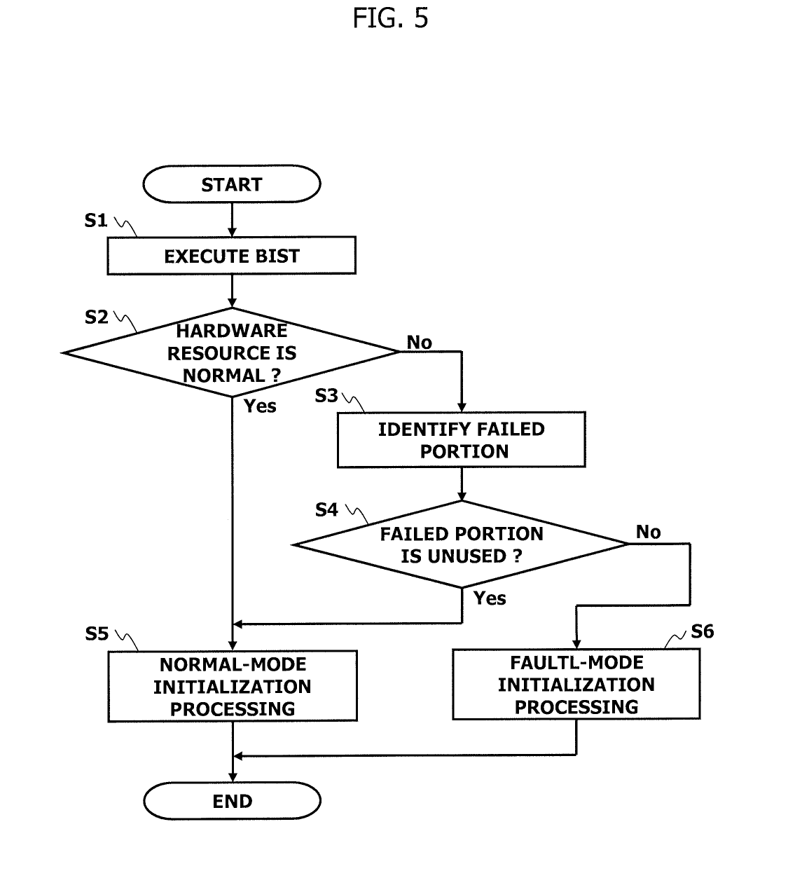

FIG. 5 illustrates an example of initialization processing that CPU 342 of microcomputer 340 executes according to control programs stored in ROM 346 in response to power-on of electronic control apparatus 300.

In step 1 (in the drawings, simply referred to as “S1” and the same for subsequent steps), CPU 342 of microcomputer 340 executes BIST 360 incorporated in microcomputer 340. More specifically, CPU 342 of microcomputer 340 checks whether a hardware resource has failed, based on an output signal of comparator circuit 364 in BIST 360. Here, BIST 360 checks whether a fault has occurred in each group that provides a predetermined function, more specifically, in CPU 342, RAM 344, ROM 346, timer 348, I/O circuit 350, and A/D converter 352 as described above.

In step 2, CPU 342 of microcomputer 340 determines whether a fault has occurred in any hardware resource in microcomputer 340 based on the result of execution of BIST 360. Then, if it is determined that all hardware resources are normal (Yes), the operation of CPU 342 of microcomputer 340 proceeds to step 5. On the other hand, if it is determined that any hardware resource has failed (No), the operation of CPU 342 of microcomputer 340 proceeds to step 3.

In step 3, CPU 342 of microcomputer 340 executes diagnosis functions of software on all failed hardware resources to identify a failed portion of each hardware resource (like timer C in timer 348, for example). The diagnosis functions are detailed below.

In step 4, CPU 342 of microcomputer 340 references control configuration information stored in ROM 346, for example to determine whether a failed portion of a hardware resource is unused. If it is determined that the failed portion is unused (Yes), the operation of CPU 342 of microcomputer 340 proceeds to step 5. On the other hand, if it is determined that the failed portion is used (No), the operation of CPU 342 of microcomputer 340 proceeds to step 6.

In step 5, CPU 342 of microcomputer 340 executes normal-mode initialization processing that is to be performed at a normal time when no fault is found in hardware resources of microcomputer 340. Here, conceivable examples of the normal-mode initialization processing include ‘resetting a control variable’, ‘reading various learning values, etc. from ROM 346’, and the like.

In step 6, CPU 342 of microcomputer 340 executes fault-mode initialization processing that is to be performed when a fault is found in any hardware resource of microcomputer 340. Here, the fault-mode initialization processing can be preparations for substitution processing that substitutes the function given by a failed hardware resource with a function provided by another hardware resource as detailed later.

According to such electronic control apparatus 300, CPU 342 of microcomputer 340 executes BIST 360 in response to the power-on so as to determine whether a hardware resource has failed. Then, when it is determined that the hardware resource has not failed, CPU 342 of microcomputer 340 executes normal-mode initialization processing. On the other hand, when it is determined that the hardware resource has failed, CPU 342 of microcomputer 340 identifies a failed portion by utilizing a diagnosis function of software. If a failed portion is unused, a system to be controlled is not affected thereby. In this case, CPU 342 of microcomputer 340 executes normal-mode initialization processing. If the failed portion is used, CPU 342 of microcomputer 340 executes fault-mode initialization processing in order to minimize adverse influence on the system to be controlled.

In other words, when a failed portion of a hardware resource is identified, CPU 342 of microcomputer 340 executes fault-mode initialization processing only on the function provided by the failed portion. Also, if a failed portion of a hardware resource is unused, CPU 342 of microcomputer 340 prohibits substituting for the function provided by the failed portion.

Next, the diagnosis function and the substitution processing are described in detail.

### [Diagnosis Function]

### (1) Identifying Failed Portion of Timer

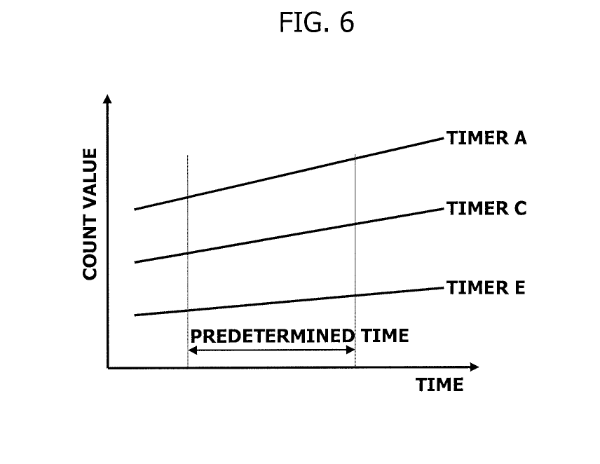

BIST 360 can check whether a fault has occurred in timer 348 that provides a timer function but cannot identify which one of the plural timers has failed. Thus, as illustrated in FIG. 6, three or more (in FIG. 6, three) timers A, C and E are used, which output pulses at different time intervals, and CPU 342 of microcomputer 340 counts the number of pulses output from each of timers A, C and E over a predetermined time. CPU 342 of microcomputer 340 then derives times from the output count values of timers A, C and E and compares these times, whereby a failed timer can be identified.

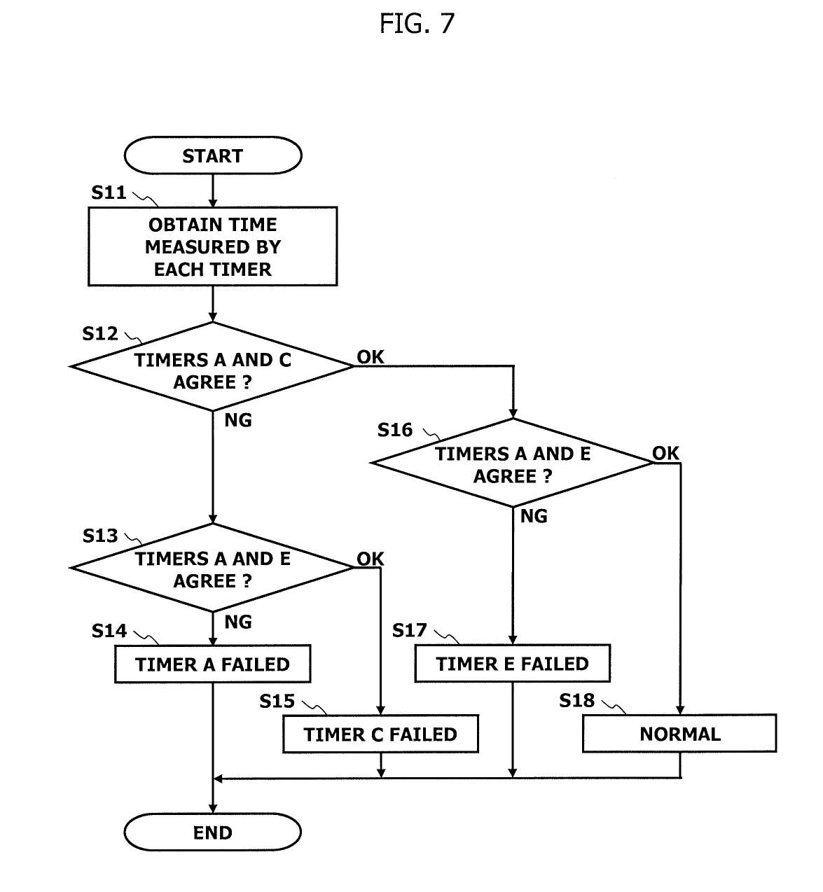

FIG. 7 illustrates an example of processing for identifying a failed portion of a timer.

In step 11, CPU 342 of microcomputer 340 counts the number of pulses output from each of timers A, C and E over a predetermined time and multiplies the count value by a time interval assigned to each pulse so as to obtain the time measured by each of timers A, C and E.

In step 12, CPU 342 of microcomputer 340 compares the time measured by timer A with that measured by timer C to determine whether their difference falls within a predetermined value. Here, the predetermined value is a threshold value for determining whether either of the two timers has failed. This value can be appropriately set according to the timer accuracy, a computational tolerance, etc., for example. If the difference in measured time is greater than the predetermined value, CPU 342 of microcomputer 340 determines that either timer A or timer C has failed (NG) and its operation proceeds to step 13. On the other hand, if the difference in measured time is within the predetermined value, CPU 342 of microcomputer 340 determines that timers A and C are normal (OK) and its operation proceeds to step 16.

In step 13, CPU 342 of microcomputer 340 compares the time measured by timer A and that measured by timer E to determine whether their difference falls within a predetermined value. If it is determined that the difference in measured time is greater than the predetermined value (NG), the operation of CPU 342 of microcomputer 340 proceeds to step 14. On the other hand, if it is determined that the difference in measured time is the predetermined value or less (OK), the operation of CPU 342 of microcomputer 340 proceeds to step 15.

In step 14, CPU 342 of microcomputer 340 identifies timer A as having failed.

In step 15, CPU 342 of microcomputer 340 identifies timer C as having failed.

In step 16, CPU 342 of microcomputer 340 compares the time measured by timer A and that measured by timer E to determine whether their difference falls within a predetermined value. If it is determined that the difference in measured time is greater than the predetermined value (NG), the operation of CPU 342 of microcomputer 340 proceeds to step 17. On the other hand, if it is determined that the difference in measured time is the predetermined value or less (OK), the operation of CPU 342 of microcomputer 340 proceeds to step 18.

In step 17, CPU 342 of microcomputer 340 identifies timer E as having failed.

In step 18, CPU 342 of microcomputer 340 identifies timers A, C and E as normal ones. That is, CPU 342 of microcomputer 340 determines that BIST 360 has diagnosed erroneously due to superimposed noise, etc., for example.

### (2) Identifying Failed Portion of I/O Circuit

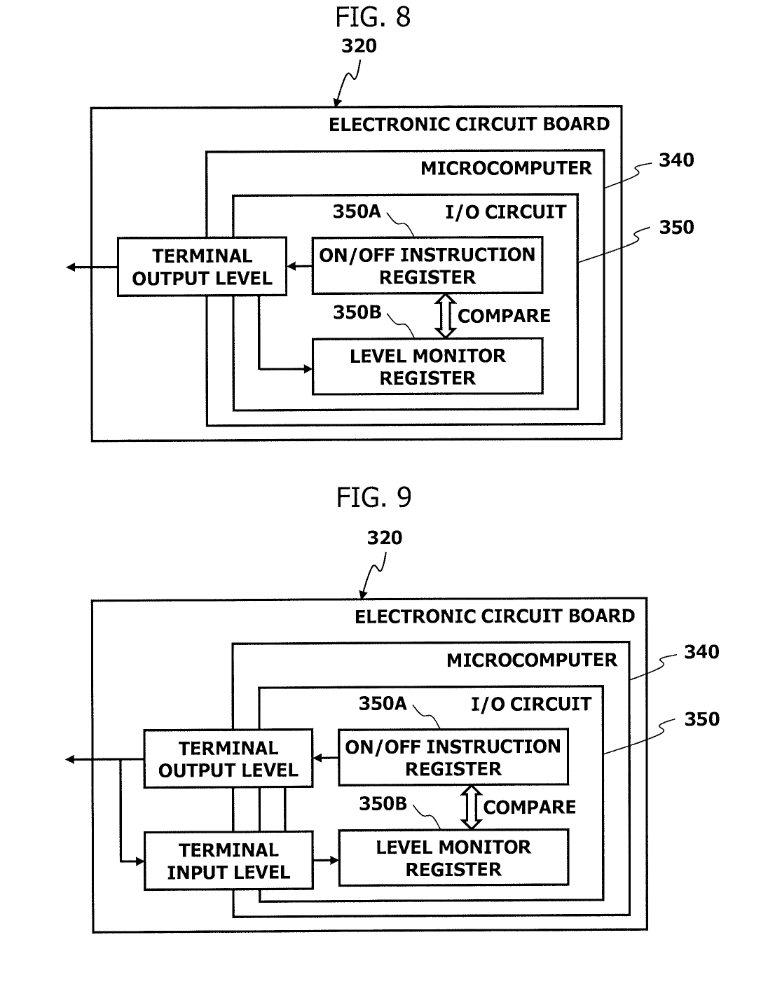

Microcomputer 340 includes plural terminals to input/output signals. However, BIST 360 can check whether a fault has occurred in I/O circuit 350 that provides an input/output function but cannot determine which one of the plural terminals provides a failed input/output function. To cope with this problem, as illustrated in FIG. 8, CPU 342 of microcomputer 340 can identify a failed terminal by comparing an instruction value of an ON/OFF instruction register 350A and an output value of a level monitor register 350B for monitoring the output of ON/OFF instruction register 350A, which are incorporated in I/O circuit 350.

Note that CPU 342 of microcomputer 340 can also use level monitor register 350B that utilizes the input terminal of electronic circuit board 320 to monitor the output, as illustrated in FIG. 9. Also, a failed portion of an input/output function can be identified not for all terminals of microcomputer 340 but only for terminals that might have a serious influence on a system to be controlled.

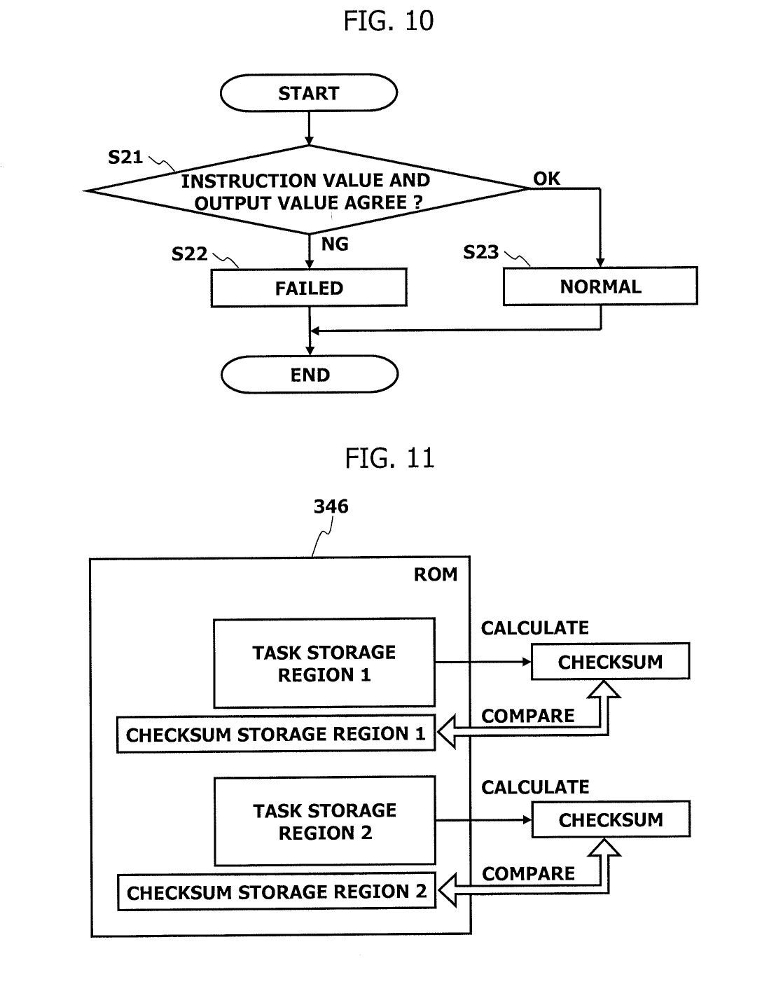

FIG. 10 illustrates an example of processing for identifying a failed portion of the I/O circuit.

In step 21, CPU 342 of microcomputer 340 compares an instruction value of ON/OFF instruction register 350A with an output value of level monitor register 350B to determine whether an instructed output is obtained. If it is determined that the instructed output is not obtained (NG), the operation of CPU 342 of microcomputer 340 proceeds to step 22. On the other hand, if it is determined that the instructed output is obtained (OK), the operation of CPU 342 of microcomputer 340 proceeds to step 23.

In step 22, CPU 342 of microcomputer 340 determines that a terminal to be diagnosed has failed.

In step 23, CPU 342 of microcomputer 340 determines that the terminal to be diagnosed has not failed.

### (3) Identifying Failed Portion of Nonvolatile Memory

In ROM 346 of microcomputer 340, allocated are task programs for controlling a system to be controlled, e.g., task storage regions 1 and 2 configured to store tasks 1 and 2, respectively as illustrated in FIG. 11. Also, in ROM 346, allocated are checksum storage regions 1 and 2 configured to store corresponding checksums (reference values) in association with tasks 1 and 2 stored in task storage regions 1 and 2, respectively. In checksum storage regions 1 and 2, checksums of tasks 1 and 2 are stored. Then, CPU 342 of microcomputer 340 calculates checksums of tasks 1 and 2 stored in task storage regions 1 and 2, respectively and compares the calculated checksums with those stored in checksum storage regions 1 and 2 so as to identify a failed portion of a storage region of ROM 346, which is incapable of correctly storing data. Note that the failed portion of ROM 346 can be identified using, for example, parity bits, etc. in place of checksums.

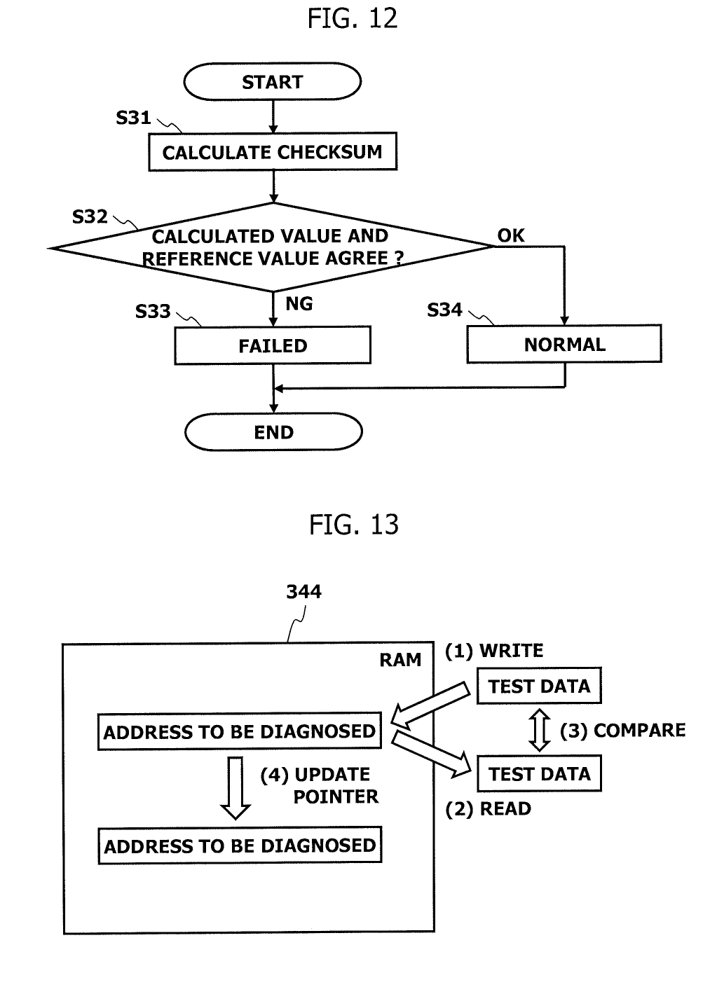

FIG. 12 illustrates an example of processing for identifying a failed portion of a nonvolatile memory.

In step 31, CPU 342 of microcomputer 340 calculates a checksum of data stored in a task storage region to be diagnosed.

In step 32, CPU 342 of microcomputer 340 compares a checksum (calculated value) of a task storage region with a checksum (reference value) in a checksum storage region to determine whether they agree. If it is determined that the calculated value and the reference value do not agree (NG), the operation of CPU 342 of microcomputer 340 proceeds to step 33. On the other hand, if it is determined that the calculated value and the reference value agree (OK), the operation of CPU 342 of microcomputer 340 proceeds to step 34.

In step 33, CPU 342 of microcomputer 340 determines that the task storage region to be diagnosed has failed.

In step 34, CPU 342 of microcomputer 340 determines that the task storage region to be diagnosed has not failed.

### (4) Identifying Failed Portion of Volatile Memory

In order to identify a failed portion of RAM 344 of microcomputer 340, a pointer indicating an address of RAM 344 is prepared. As illustrated in FIG. 13, CPU 342 of microcomputer 340 writes test data to the address indicated by the pointer (procedure 1) and reads test data therefrom (procedure 2). Furthermore, CPU 342 of microcomputer 340 compares test data written to RAM 344 with test data read from RAM 344 to determine whether a fault has occurred in RAM 344 based on whether these data agree (procedure 3). After that, CPU 342 of microcomputer 340 updates the pointer (procedure 4). In this way, CPU 342 of microcomputer 340 repeatedly executes the above processing from the beginning address to the final address of RAM 344, whereby a failed address can be identified.

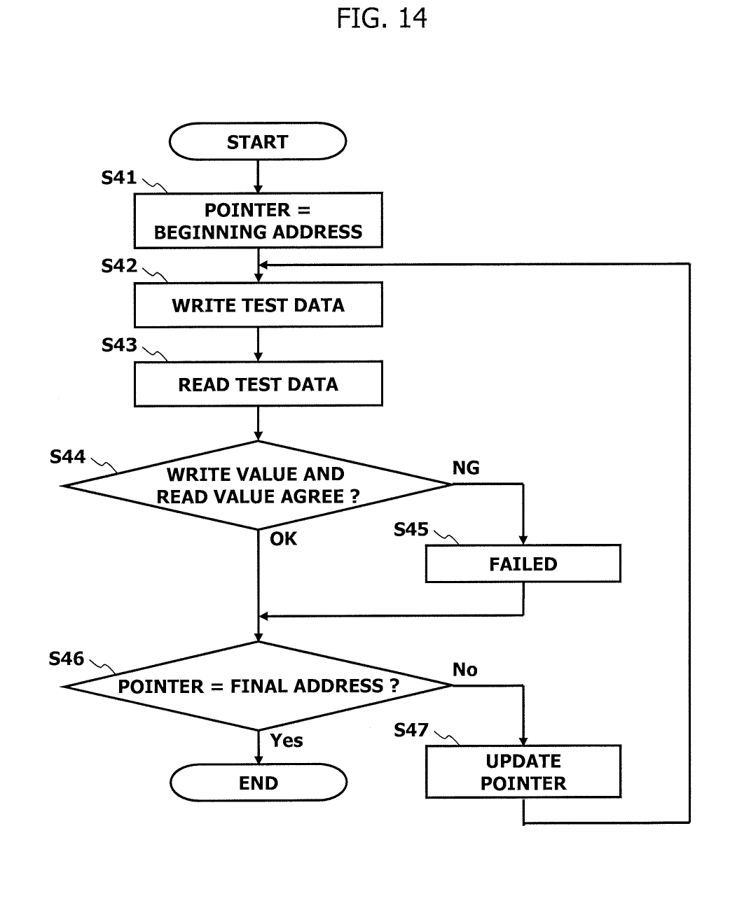

FIG. 14 illustrates an example of processing for identifying a failed portion of a volatile memory.

In step 41, CPU 342 of microcomputer 340 sets the beginning address of RAM 344 to the pointer.

In step 42, CPU 342 of microcomputer 340 writes test data to the address indicated by the pointer.

In step 43, CPU 342 of microcomputer 340 reads test data from the address indicated by the pointer.

In step 44, CPU 342 of microcomputer 340 compares test data written to RAM 34 (write value) and test data read from RAM 344 (read value) to determine whether they agree. Then, if it is determined that the write value and the read value agree (OK), the operation of CPU 342 of microcomputer 340 proceeds to step 46. On the other hand, if it is determined that the write value and the read value do not agree (NG), the operation of CPU 342 of microcomputer 340 proceeds to step 45.

In step 45, CPU 342 of microcomputer 340 determines that a fault has occurred at the address indicated by the pointer due to improper bonding of any element, for example. After that, the operation of CPU 342 of microcomputer 340 proceeds to step 46.

In step 46, CPU 342 of microcomputer 340 determines whether the pointer indicates the final address of RAM 344, i.e., whether all regions of RAM 344 have been checked. If it is determined that the pointer indicates the final address of RAM 344 (Yes), CPU 342 of microcomputer 340 terminates its operation. On the other hand, if it is determined that the pointer does not indicate the final address of RAM 344 (No), the operation of CPU 342 of microcomputer 340 proceeds to step 47.

In step 47, the CPU 342 of microcomputer 340 updates the pointer, i.e., sets the pointer to indicate the next address corresponding to test data, of RAM 344. After that, the operation of CPU 342 of microcomputer 340 returns to step 42.

Regarding the other hardware resources, i.e., CPU 342 and A/D converter 352, whether a fault has occurred can be determined, for example, by comparing output data obtained when predetermined data is input, and a corresponding expected value. Also, hardware resources of microcomputer 340 can include ones for providing functions other than CPU 342, RAM 344, ROM 346, timer 348, I/O circuit 350, and A/D converter 352.

### [Substitution Processing]

### (1) Timer

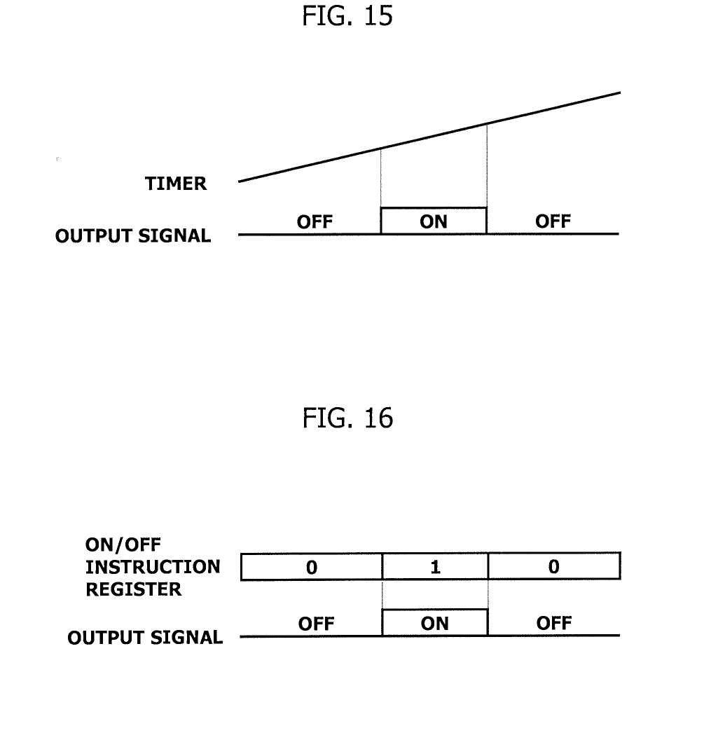

Regarding ignition control for internal combustion engine 100, timer 348 utilizes a compare match function to output an ON signal when a predetermined timing is reached as illustrated in FIG. 15. In order to substitute for this timer function, CPU 342 of microcomputer 340 writes 0 or 1 to ON/OFF instruction register 350A of I/O circuit 350 at a timing corresponding to an operational state of internal combustion engine 100 as illustrated in FIG. 16. When 1 is written to ON/OFF instruction register 350A of I/O circuit 350, an ON signal is output therefrom. This provides substantially the same function as timer 348. Here, when 0 or 1 is written to ON/OFF instruction register 350A of I/O circuit 350, it takes some time for its output to change, but the required time is not so long as to hinder the substitution processing for the timer function.

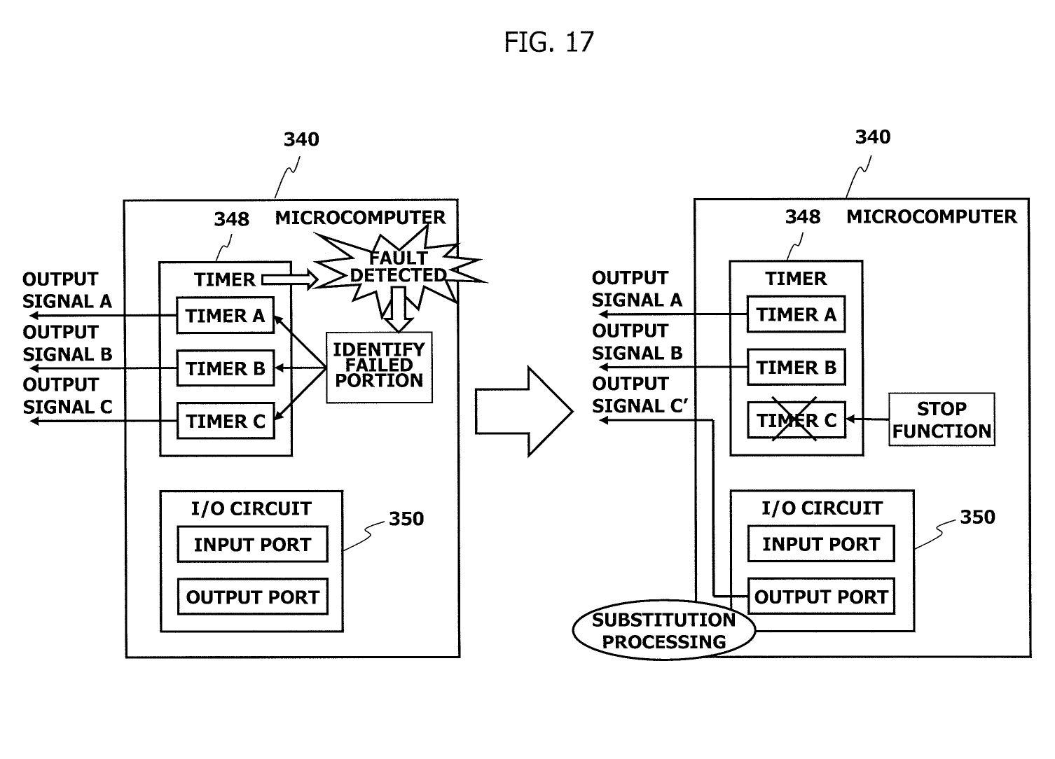

With the above configuration, as illustrated in FIG. 17, if a fault is found in timer C of timer 348, for example, the function of timer C is stopped and a substitute output signal C′ is output from I/O circuit 350. Hence, it is possible to avoid a situation in which all the timer functions of timer 348 are stopped to disable ignition control for internal combustion engine 100, for example. At this time, ignition control is delayed somewhat, but controllability sufficient for at least limp-home control can be ensured. Note that if a predetermined terminal of microcomputer 340 is a multi-functional one capable of providing plural selectable functions, the terminal's function can be switched to a desired one.

### (2) Volatile Memory

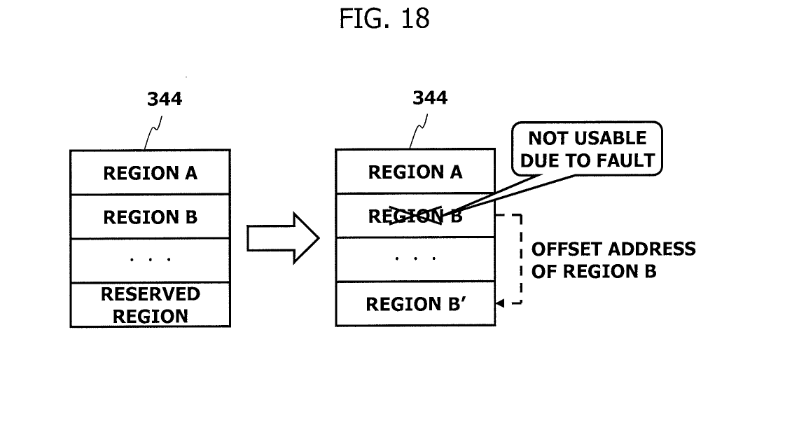

As illustrated in FIG. 18, RAM 344 of microcomputer 340 is logically divided into regions A, B, . . . , and reserved region. If a fault is found in region B, for example, CPU 342 of microcomputer 340 prohibits the use of region B as well as offsets the address to region B, for example, in order to use the reserved region as a substitute (substitute region B′) for region B.

With this configuration, if a fault is found in a certain region of RAM 344, the use of this region is prohibited and also, a reserved region is used in place of the failed region. Accordingly, it is possible to ensure functional safety by prohibiting the use of a failed region and to execute substantially the same control as in a normal time.

### (3) Arithmetic Unit (CPU)

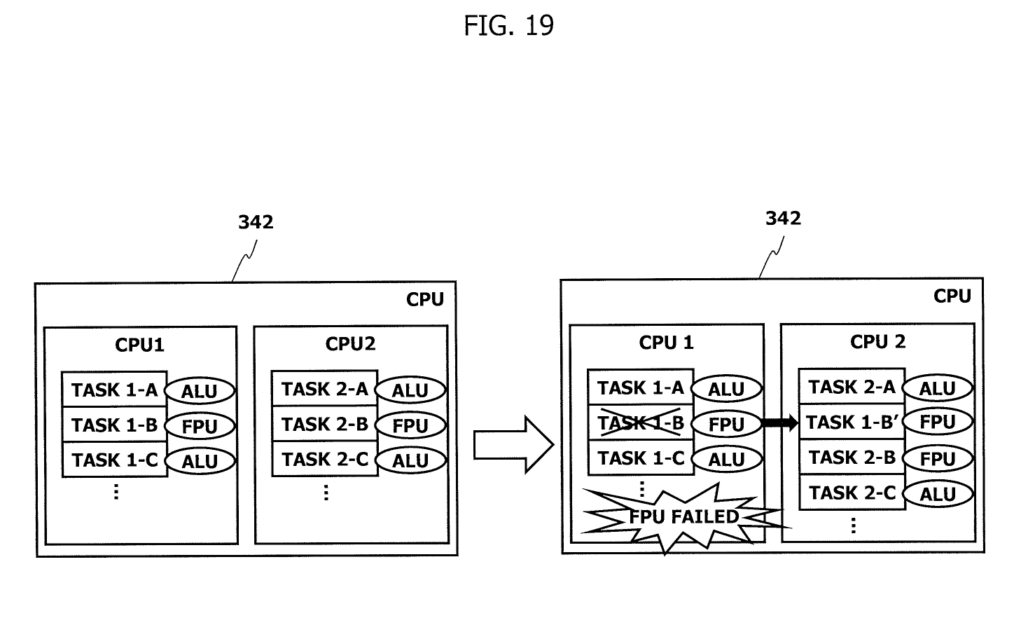

The case here considered is that CPU 342 of microcomputer 340 is a multicore processor with CPUs 1 and 2 as illustrated in FIG. 19. CPUs 1 and 2 include an ALU (Arithmetic Logic Unit) for logic operation, addition, and subtraction, and an FPU (Floating Point Unit) dedicated to floating-point operation. In CPU 1, if a fault is found in an FPU that is executing a task 1-B, task 1-B executed by the FPU of CPU 1 is transferred to an FPU of CPU 2 and carried out there.

With this configuration, even if a fault is found in a certain portion of CPU 342, more specifically, ALU or FPU, CPU 342 can ensure the same controllability as conventionally without shifting to fail-safe processing.

Accordingly, even if a fault has occurred in any hardware resource of electronic control apparatus 300, the function provided by the failed hardware resource is substituted by another hardware resource, whereby a system to be controlled can be continuously controlled.

### REFERENCE SYMBOL LIST

300 Electronic control apparatus
340 Microcomputer
342 CPU (processor, hardware resource)
344 RAM (hardware resource)
346 ROM (hardware resource)
348 Timer (hardware resource)
350 I/O circuit (hardware resource)
352 A/D converter (hardware resource)
360 BIST (diagnosis circuit)

1.-15. (canceled)

16. An electronic control apparatus comprising a microcomputer that incorporates a diagnosis circuit configured to determine whether a fault has occurred in a hardware resource for each group that provides the same function, and a processor,
the processor being configured to, when the diagnosis circuit determines that the hardware resource has failed, execute a diagnosis function of software to identify a failed portion of the hardware resource in a corresponding group and substitute a function provided by the failed portion with a function provided by another hardware resource.

17. The electronic control apparatus according to claim 16, wherein the processor is configured to, when the hardware resource, determined as having failed by the diagnosis circuit, is unused, prohibit substituting a function provided by the hardware resource with a function provided by another hardware resource.

18. The electronic control apparatus according to claim 16, wherein the processor is configured to, when the hardware resource comprises at least three timers, compare times measured by the at least three timers to identify a failed one of the three timers.

19. The electronic control apparatus according to claim 16, wherein the processor is configured to, when the hardware resource comprises a plurality of I/O circuits, compare an instruction value of each of the I/O circuits with a corresponding output value to identify a failed one of the I/O circuits.

20. The electronic control apparatus according to claim 16, wherein the processor is configured to, when the hardware resource comprises a nonvolatile memory, compare a value derived from data stored in a predetermined region of the nonvolatile memory with a reference value of the data stored in the predetermined region of the nonvolatile memory to identify the failed, predetermined region.

21. The electronic control apparatus according to claim 16, wherein the processor is configured to, when the hardware resource comprises a volatile memory, compare data written to a predetermined address of the volatile memory with data read from the predetermined address of the volatile memory to identify a failed address of the volatile memory.

22. The electronic control apparatus according to claim 16, wherein the processor is configured to, when the hardware resource comprises a timer, substitute a signal output from the timer with a signal output from an I/O circuit.

23. The electronic control apparatus according to claim 16, wherein the processor is configured to, when the hardware resource comprises a nonvolatile memory, offset an address to a failed, predetermined region to a substitute address to a reserved region that is allocated in the nonvolatile memory.

24. The electronic control apparatus according to claim 16, wherein the processor is configured to, when the hardware resource comprises a multicore processor, substitute a failed core with another core.

25. An electronic control method comprising the step of utilizing a microcomputer incorporating a diagnosis circuit configured to determine whether a fault has occurred in a hardware resource for each group that provides the same function to, when the diagnosis circuit determines that the hardware resource has failed, execute a diagnosis function of software to identify a failed portion of the hardware resource in a corresponding group and substitute a function provided by the failed portion with a function provided by another hardware resource.

26. The electronic control method according to claim 25, wherein when the hardware resource, determined as having failed by the diagnosis circuit, is unused, the microcomputer prohibits substituting a function provided by the hardware resource with a function provided by another hardware resource.
